(19) United States
(12) Patent Application Publication
(10) Pub. No.: US 2024/0261932 A1
(43) Pub. Date: Aug. 8, 2024

(54) SUBSTRATE PROCESSING APPARATUS AND SUBSTRATE PROCESSING METHOD

(71) Applicant: EBARA CORPORATION, Tokyo (JP)

(72) Inventors: Yuichi SATO, Tokyo (JP); Kohei OHSHIMA, Tokyo (JP)

(21) Appl. No.: 18/562,950

(22) PCT Filed: Apr. 15, 2022
(86) PCT No.: PCT/JP2022/017904

§ 371 Date: Nov. 21, 2023

(30) Foreign Application Priority Data
May 24, 2021 (JP) 2021-087056

(51) Int. Cl. B24B 49/10; B24B 37/10; B24B 49/18

(52) U.S. Cl. CPC B24B 49/10; B24B 37/10; B24B 49/186

(57) ABSTRACT

To measure an amount of abrasion of a polishing pad with a simple structure.

A substrate processing apparatus 1000 includes: a table 100 for supporting a substrate WF with a surface to be polished facing upward; a pad holder 226 for holding a polishing pad 222 for polishing the substrate WF supported by the table 100; an elevating mechanism 260 for moving up and down the polishing pad 222 held to the pad holder 226; and an abrasion amount measurement member 270 configured to lower the polishing pad 222 by the elevating mechanism 260 and measure the amount of abrasion of the polishing pad 222 based on a value correlated with a behavior of the elevating mechanism 260 until the polishing pad contacts a reference surface.

### TECHNICAL FIELD

This application relates to a substrate processing apparatus and a substrate processing method. This application claims priority from Japanese Patent Application No. 2021-087056 filed on May 24, 2021. The entire disclosure including the descriptions, the claims, the drawings, and the abstracts in Japanese Patent Application No. 2021-087056 is herein incorporated by reference.

### BACKGROUND ART

There is a Chemical Mechanical Polishing (CMP) apparatus as one kind of a substrate processing apparatus used for a semiconductor processing process. The CMP apparatus can be roughly classified into “a face-up type (a system in which a surface to be polished of a substrate faces upward)” and “a face-down type (a system in which a surface to be polished of a substrate faces downward)” depending on a direction that the surface to be polished of the substrate faces.

PTL 1 discloses a face-up type CMP apparatus that polishes a substrate by bringing a polishing pad having a diameter smaller than that of the substrate into contact with the substrate while rotating the polishing pad. Additionally, PTL 2 discloses a face-up type CMP apparatus that measures a thickness of a polishing pad.

### CITATION LIST

### Patent Literature

PTL 1: Japanese Unexamined Patent Application Publication No. 2003-229388
PTL 2: Japanese Unexamined Patent Application Publication No. 2004-25413

### SUMMARY OF INVENTION

### Technical Problem

However, the prior art is not considered to measure an amount of abrasion of a polishing pad with a simple structure.

That is, the technique disclosed in PTL 2 provides a contact stylus displacement meter in a CMP apparatus to measure the thickness of the polishing pad. Accordingly, since a dedicated space for disposing the contact stylus displacement meter is required, the entire CMP apparatus increases in size and becomes complicated.

Therefore, an object of this application is to measure an amount of abrasion of a polishing pad with a simple structure.

### Solution to Problem

According to one embodiment, there is disclosed a substrate processing apparatus that includes a table, a pad holder, an elevating mechanism, and an abrasion amount measurement member. The table is for supporting a substrate with a surface to be polished facing upward. The pad holder is for holding a polishing pad for polishing the substrate supported by the table. The elevating mechanism is for moving up and down the polishing pad held to the pad holder. The abrasion amount measurement member is configured to lower the polishing pad by the elevating mechanism and measure an amount of abrasion of the polishing pad based on a value correlated with a behavior of the elevating mechanism until the polishing pad contacts a reference surface.

### BRIEF DESCRIPTION OF DRAWINGS

FIG. 1 is a perspective view schematically illustrating an overall configuration of a substrate processing apparatus according to one embodiment.

FIG. 2 is a plan view schematically illustrating the overall configuration of the substrate processing apparatus according to one embodiment.

FIG. 3 is a perspective view schematically illustrating a multi-axis arm according to one embodiment.

FIG. 4 is a perspective view schematically illustrating a pad holder according to one embodiment.

FIG. 5 is a cross-sectional view schematically illustrating the pad holder according to one embodiment.

FIG. 6A is a diagram schematically illustrating abrasion measurement of a polishing pad according to a first embodiment.

FIG. 6B is a diagram schematically illustrating the abrasion measurement of the polishing pad according to the first embodiment.

FIG. 7A is a flowchart depicting the abrasion measurement of the polishing pad according to the first embodiment.

FIG. 7B is a flowchart depicting the abrasion measurement of the polishing pad according to the first embodiment.

FIG. 8A is a diagram schematically illustrating abrasion measurement of a polishing pad according to a second embodiment.

FIG. 8B is a diagram schematically illustrating the abrasion measurement of the polishing pad according to the second embodiment.

FIG. 9A is a flowchart depicting the abrasion measurement of the polishing pad according to the second embodiment.

FIG. 9B is a flowchart depicting the abrasion measurement of the polishing pad according to the second embodiment.

FIG. 10A is a diagram schematically illustrating abrasion measurement of a polishing pad according to a third embodiment.

FIG. 10B is a diagram schematically illustrating the abrasion measurement of the polishing pad according to the third embodiment.

FIG. 11A is a flowchart depicting the abrasion measurement of the polishing pad according to the third embodiment.

FIG. 11B is a flowchart depicting the abrasion measurement of the polishing pad according to the third embodiment.

FIG. 11C is a flowchart depicting abrasion measurement of a polishing pad according to a modification of the third embodiment.

### DESCRIPTION OF EMBODIMENTS

The following describes embodiments of a substrate processing apparatus and a substrate processing method according to the present invention with reference to the attached drawings. In the attached drawings, identical or similar reference numerals are attached to identical or similar components, and overlapping description regarding the identical or similar components may be omitted in the description of the respective embodiments. Features described in the respective embodiments are applicable to other embodiments in so far as they are consistent with one another.

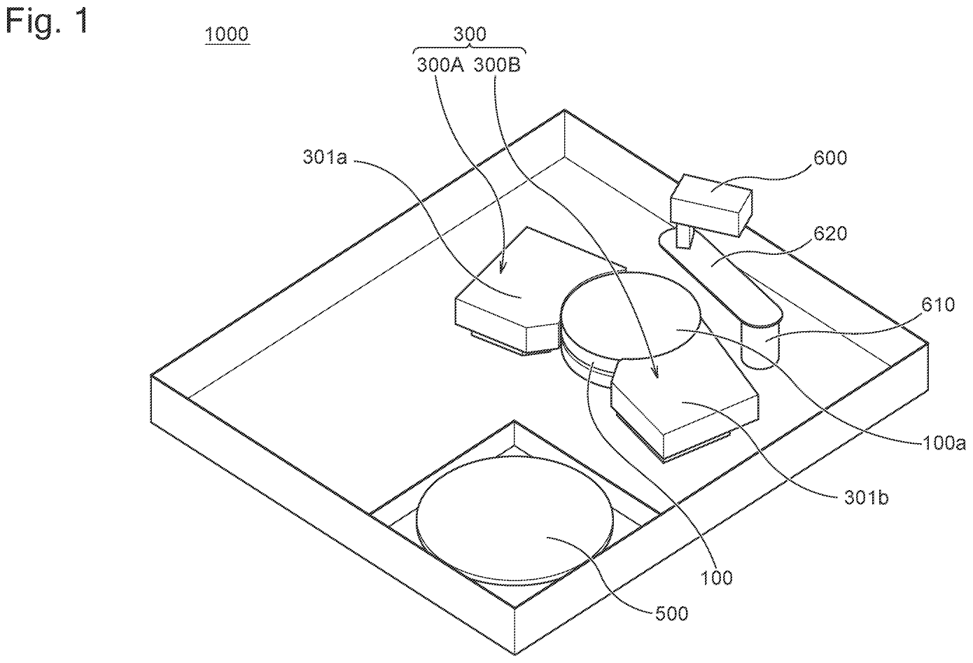

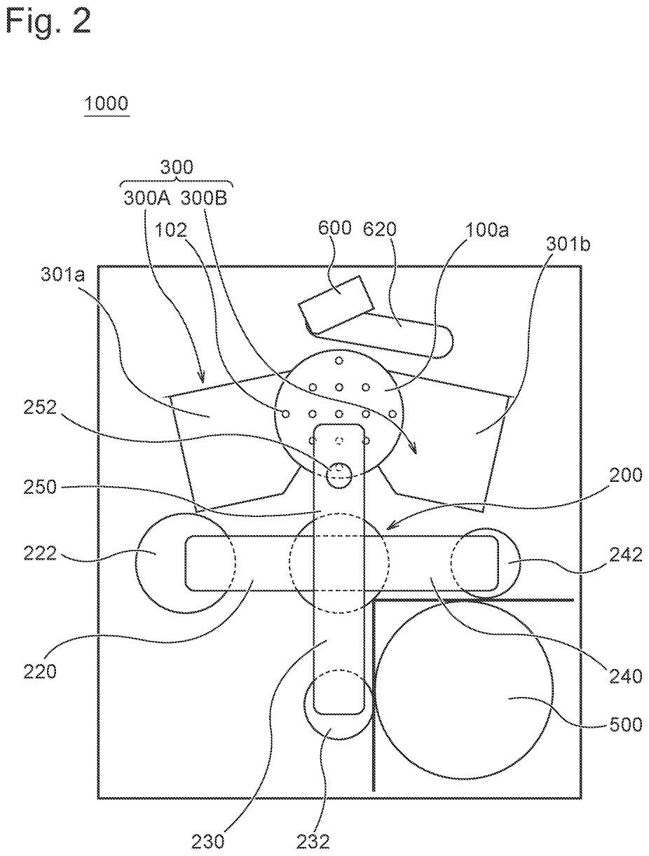

FIG. 1 is a perspective view schematically illustrating an overall configuration of the substrate processing apparatus according to one embodiment. FIG. 2 is a plan view schematically illustrating the overall configuration of the substrate processing apparatus according to one embodiment. A substrate processing apparatus 1000 illustrated in FIG. 1 and FIG. 2 includes a table 100, a multi-axis arm 200, supporting members 300A, 300B, a dresser 500, and a film thickness measuring instrument (end point detector) 600. In FIG. 1, the multi-axis arm 200 is omitted for clarification of illustration.

### <Table>

The table 100 is a circular-plate-shaped member for supporting a circular-plate-shaped substrate WF such that a surface to be polished of the substrate WF as a process target faces upward in the vertical direction. In one embodiment, the table 100 includes a support surface 100a for supporting a back surface opposite to the surface to be polished of the substrate WF and is configured to be rotatable by a driving mechanism, such as a motor (not illustrated). The support surface 100a has a plurality of holes 102, and the table 100 is configured to ensure performing vacuum suction on the substrate WF via the holes 102. The substrate processing apparatus 1000 of this embodiment is a face-up type substrate processing apparatus that polishes the substrate WF with the surface to be polished of the substrate WF facing upward.

### <Multi-Axis Arm>

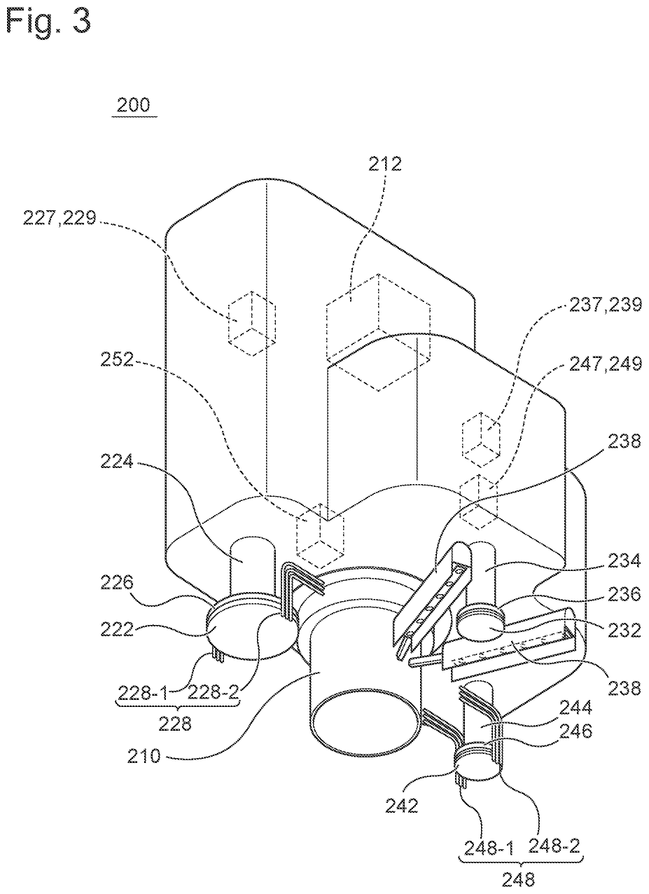

FIG. 3 is a perspective view schematically illustrating the multi-axis arm according to one embodiment. As illustrated in FIG. 2 and FIG. 3, the multi-axis arm 200 is a member that holds a plurality of processing tools for performing various processes on the substrate WF supported by the table 100 and is arranged adjacent to the table 100. The multi-axis arm 200 in this embodiment is configured to hold a large-diameter, circular-plate-shaped polishing pad 222 for polishing the substrate WF, a circular-plate-shaped cleaning tool 232 for cleaning the substrate WF, a small-diameter, circular-plate-shaped polishing pad 242 for finish polishing of the substrate WF, and an imaging member (camera) 252 for measuring a diameter of the substrate WF.

The multi-axis arm 200 includes: a swing shaft 210 extending in a direction perpendicular to the substrate WF (height direction); a rotation drive mechanism 212, such as a motor, that rotatably drives the swing shaft 210; and a first arm 220, a second arm 230, a third arm 240, and a fourth arm 250 that are supported by the swing shaft 210 and radially arranged around the swing shaft 210.

To the first arm 220, a rotation shaft 224 that extends in the height direction is mounted, and to a distal end of the rotation shaft 224, a circular-plate-shaped pad holder 226 is mounted. The large-diameter polishing pad 222 is held to the pad holder 226. The multi-axis arm 200 includes a holder elevating mechanism 227 for moving up and down the pad holder 226 with respect to the substrate WF. For example, the holder elevating mechanism 227 can be achieved by a known mechanism, such as a servomotor. The multi-axis arm 200 includes a pad rotation mechanism 229 for rotating the pad holder 226. For example, the pad rotation mechanism 229 can be achieved by a known mechanism, such as a motor, and can rotate the pad holder 226 by rotating the rotation shaft 224.

The multi-axis arm 200 includes nozzles 228 arranged around the pad holder 226. The nozzles 228 are configured to supply polishing liquid (slurry) to the substrate WF. The nozzles 228 include a first nozzle 228-1 arranged on a swing path of the pad holder 226 and a second nozzle 228-2 arranged on a swing path of the pad holder 226 on a side opposite to the first nozzle 228-1 across the pad holder 226. The first nozzle 228-1 and the second nozzle 228-2 are each configured to supply the polishing liquid to the surface to be polished of the substrate WF.

To the second arm 230, a rotation shaft 234 that extends in the height direction is mounted, and to a distal end of the rotation shaft 234, a circular-plate-shaped cleaning tool holder 236 is mounted. The cleaning tool 232 is held to the cleaning tool holder 236. The multi-axis arm 200 includes a holder elevating mechanism 237 for moving up and down the cleaning tool holder 236 with respect to the substrate WF. For example, the holder elevating mechanism 237 can be achieved by a known mechanism, such as a servomotor. The multi-axis arm 200 includes a cleaning tool rotation mechanism 239 for rotating the cleaning tool holder 236. For example, the cleaning tool rotation mechanism 239 can be achieved by a known mechanism, such as a motor, and can rotate the cleaning tool holder 236 by rotating the rotation shaft 234.

The multi-axis arm 200 includes atomizers 238 for supplying a cleaning liquid around the cleaning tool holder 236. The atomizers 238 are arranged on both sides in the swinging direction of the cleaning tool holder 236 across the cleaning tool holder 236, and are configured to discharge the cleaning liquid to the substrate WF.

To the third arm 240, a rotation shaft 244 that extends in the height direction is mounted, and to a distal end of the rotation shaft 244, a circular-plate-shaped pad holder 246 is mounted. The small-diameter polishing pad 242 is held to the pad holder 246. The multi-axis arm 200 includes a holder elevating mechanism 247 for moving up and down the pad holder 246 with respect to the substrate WF. For example, the holder elevating mechanism 247 can be achieved by a known mechanism, such as a servomotor. The multi-axis arm 200 includes a pad rotation mechanism 249 for rotating the pad holder 246. For example, the pad rotation mechanism 249 can be achieved by a known mechanism, such as a motor, and can rotate the pad holder 246 by rotating the rotation shaft 244. To the fourth arm 250, the imaging member 252 is held.

The multi-axis arm 200 includes nozzles 248 for supplying the polishing liquid around the pad holder 246. The nozzles 248 include a first nozzle 248-1 arranged on a swing path of the pad holder 246 and a second nozzle 248-2 arranged on a swing path of the pad holder 246 on a side opposite to the first nozzle 248-1 across the pad holder 246. The first nozzle 248-1 and the second nozzle 248-2 are configured to supply the polishing liquid to the surface to be polished of the substrate WF.

As illustrated in FIG. 2, in this embodiment, the first arm 220, the second arm 230, the third arm 240, and the fourth arm 250 radially extend around the swing shaft 210 while being displaced counterclockwise by 90 degrees in plan view. Rotatably driving the swing shaft 210 by the rotation drive mechanism 212 allows moving any of the large-diameter polishing pad 222, the cleaning tool 232, the small-diameter polishing pad 242, and the imaging member 252 onto the substrate WF. Rotatably driving the swing shaft 210 by the rotation drive mechanism 212 allows moving the polishing pad 222 or the polishing pad 242 onto the dresser 500. The rotation drive mechanism 212 has a function of a swing mechanism that rotatably drives the swing shaft 210 clockwise and counterclockwise in alternation to swing the first arm 220, the second arm 230, the third arm 240, and the fourth arm 250. Specifically, the rotation drive mechanism 212 rotatably drives the swing shaft 210 clockwise and counterclockwise in alternation in a state where the polishing pad 222, the cleaning tool 232, or the polishing pad 242 is positioned on the substrate WF to allow the polishing pad 222 (the pad holder 226), the cleaning tool 232 (the cleaning tool holder 236), or the polishing pad 242 (the pad holder 246) to swing with respect to the substrate WF. While this embodiment shows an example in which the polishing pad 222, the cleaning tool 232, or the polishing pad 242 is turned and swung in the radial direction of the substrate WF, that is, moved in a reciprocating manner along an arc by the rotation drive mechanism 212, the configuration is not limited to this. For example, the swing mechanism can have a configuration that linearly swings the polishing pad 222, the cleaning tool 232, or the polishing pad 242 in the radial direction of the substrate, that is, moves it in a reciprocating manner along a straight line.

For example, in a case where the polishing pad 222 is on the substrate WF, the substrate processing apparatus 1000 is configured to rotate the table 100 and rotate the polishing pad 222, and swing the polishing pad 222 by the rotation drive mechanism 212 while pressing the polishing pad 222 against the substrate WF by the holder elevating mechanism 227 to polish the substrate WF.

### <Supporting Members>

As illustrated in FIG. 1 and FIG. 2, the substrate processing apparatus 1000 includes a first supporting member 300A arranged on a swing path of the polishing pad 222 outside the table 100 and a second supporting member 300B arranged on a swing path of the polishing pad 222 on a side opposite to the first supporting member 300A across the table 100. The first supporting member 300A and the second supporting member 300B are linearly symmetrical across the substrate WF. In view of this, the following will collectively describe the first supporting member 300A and the second supporting member 300B as supporting members 300 appropriately. While the following will give a description on the function of the supporting members 300 in a case where the large-diameter polishing pad 222 is swung with respect to the substrate WF as an example, the same applies to the cleaning tool 232 or the small-diameter polishing pad 242.

The supporting members 300 are members for supporting the polishing pad 222 swung to the outside of the table 100 by the rotation of the swing shaft 210. That is, the substrate processing apparatus 1000 is configured to swing (overhang) the polishing pad 222 until the polishing pad 222 projects to outside of the substrate WF when polishing the substrate WF to uniformly polish the surface to be polished of the substrate WF. Here, in a case where the polishing pad 222 is overhung, due to various factors, such as an inclination of the pad holder 226, a pressure of the polishing pad 222 concentrates on a periphery edge portion of the substrate WF, and the surface to be polished of the substrate WF may possibly fail to be uniformly polished. Therefore, the substrate processing apparatus 1000 in this embodiment includes the supporting members 300 for supporting the polishing pad 222 overhung to the outside of the substrate WF on both sides of the table 100.

The first supporting member 300A and the second supporting member 300B respectively include support surfaces 301a, 301b that can support an entire polishing surface 222c of the polishing pad 222 in contact with the substrate WF. That is, the support surfaces 301a, 301b each have an area larger than an area of the polishing surface 222c of the polishing pad 222, and therefore even when the polishing pad 222 completely overhangs to the outside of the substrate WF, the entire polishing surface 222c is supported by the support surfaces 301a, 301b. Thus, in this embodiment, when the polishing pad 222 swings on the substrate WF, the entire polishing surface of the polishing pad 222 contacts the substrate WF while being supported, and when the polishing pad 222 swings up to the outside of the table 100, the entire polishing surface is supported by the supporting members 300. Accordingly, the polishing pad 222 does not protrude from the surface to be polished of the substrate WF or the regions of the support surfaces 301a, 301b during swinging.

### <Film Thickness Measuring Instrument>

As illustrated in FIG. 1 and FIG. 2, the substrate processing apparatus 1000 includes the film thickness measuring instrument 600 for measuring a film thickness profile of the surface to be polished of the substrate WF while polishing the substrate WF. The film thickness measuring instrument 600 can be configured of various sensors, such as an eddy current sensor or an optical sensor. As illustrated in FIG. 1, a rotation shaft 610 that extends in the height direction is arranged adjacent to the table 100. The rotation shaft 610 is rotatable about an axis of the rotation shaft 610 by a rotation drive mechanism, such as a motor (not illustrated). The rotation shaft 610 includes a swing arm 620, and the film thickness measuring instrument 600 is mounted to a distal end of the swing arm 620. The film thickness measuring instrument 600 is configured to pivotally swing about the axis of the rotation shaft 610 by the rotation of the rotation shaft 610. Specifically, the film thickness measuring instrument 600 can swing along the radial direction of the substrate WF by the rotation of the rotation shaft 610 during polishing of the substrate WF. The film thickness measuring instrument 600 is configured to swing to a position moved away from above the substrate WF while the polishing pad 222 is swinging above the substrate WF, and to swing above the substrate WF while the polishing pad 222 is not swinging above the substrate WF. That is, the film thickness measuring instrument 600 is allowed to swing above the substrate WF at timings where it does not interfere with the polishing pad 222 swinging above the substrate WF, and can measure the film thickness profile of the substrate WF polished by the polishing pad 222 over time. The film thickness measuring instrument 600 can detect an ending point of the polishing of the substrate WF when the measured film thickness profile of the substrate WF reaches a desired film thickness profile.

### <Dresser>

As illustrated in FIG. 1 and FIG. 2, the dresser 500 is arranged on turning paths of the polishing pads 222, 242 by the rotation of the swing shaft 210. Diamond particles or the like are firmly electrodeposited on the surface of the dresser 500. The dresser 500 is a circular-plate-shaped member for dressing the polishing pads 222, 242. The dresser 500 is configured to be rotated by a rotation drive mechanism, such as a motor (not illustrated). Pure water can be supplied to the surface of the dresser 500 from a nozzle (not illustrated). The substrate processing apparatus 1000 rotates the dresser 500 while supplying pure water from the nozzle to the dresser 500, rotates the polishing pads 222, 242, and swings the polishing pads 222, 242 with respect to the dresser 500 while pressing the polishing pads 222, 242 against the dresser 500. Thus, the dresser 500 scrapes off the polishing pads 222, 242 to dress polishing surfaces of the polishing pads 222, 242.

### <Pad Holder>

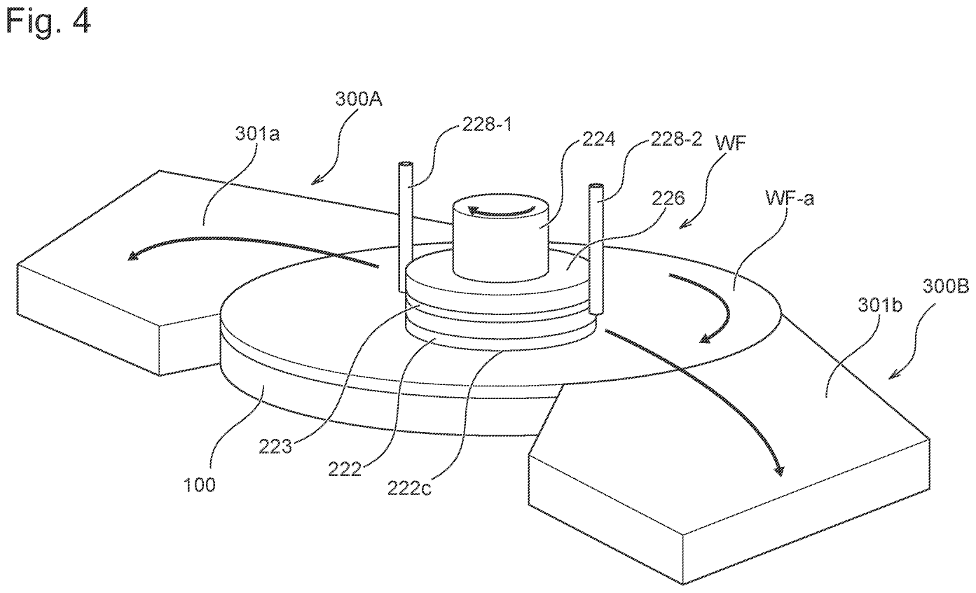

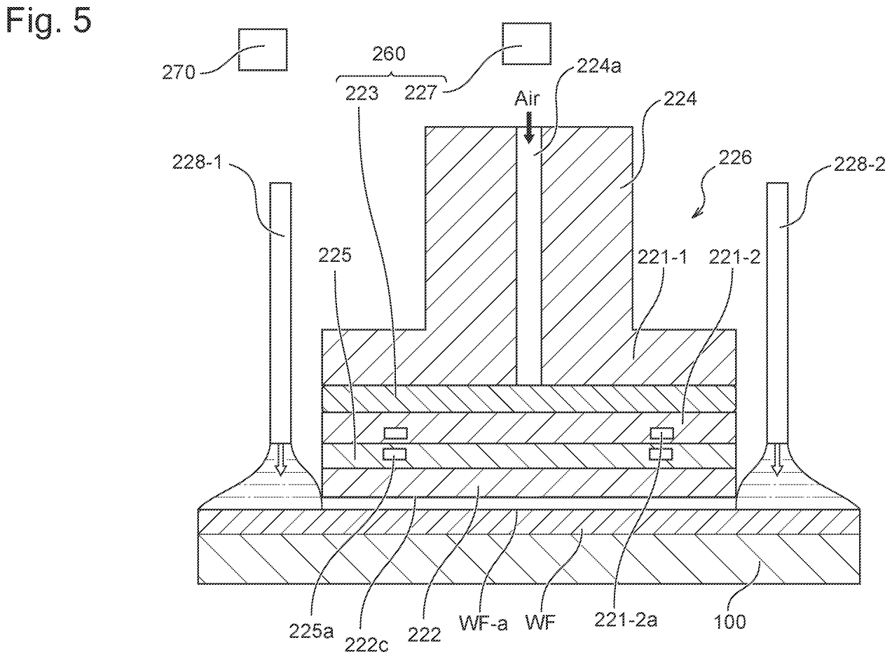

FIG. 4 is a perspective view schematically illustrating the pad holder according to one embodiment. FIG. 5 is a cross-sectional view schematically illustrating the pad holder according to one embodiment. The configuration of the pad holder 226 will be described below, and the pad holder 246 also has the similar configuration.

As illustrated in FIG. 5, the pad holder 226 includes a circular-plate-shaped first holder main body 221-1 mounted to a lower end of the rotation shaft 224 and a circular-plate-shaped second holder main body 221-2 arranged below the first holder main body 221-1. The multi-axis arm 200 includes an elevating mechanism 260 for the polishing pad 222 held to the pad holder 226 to move up and down. The elevating mechanism 260 includes the above-described holder elevating mechanism 227 configured to move up and down the pad holder 226 to move up and down the polishing pad 222. Additionally, the elevating mechanism 260 includes a bag member (air bag 223) that expands and contracts caused by inflow and outflow of a fluid (for example, air) to move up and down the polishing pad 222. The air bag 223 is arranged to be sandwiched between the first holder main body 221-1 and the second holder main body 221-2. However, the air bag 223 is not limited to this embodiment and only needs to be mounted to the pad holder 226. A flow passage 224a communicated with the air bag 223 is formed in the rotation shaft 224 and the first holder main body 221-1. The multi-axis arm 200 can adjust the pressing force of the polishing pad 222 against the substrate WF by supplying a gas to the air bag 223 from a fluid source (not illustrated) via the flow passage 224a to lower the polishing pad 222.

As illustrated in FIG. 5, to a lower surface of the second holder main body 221-2, a circular-plate-shaped pad table 225 is mounted. Specifically, magnets 221-2a are embedded into the second holder main body 221-2, and magnets 225a are embedded into the pad table 225. The pad table 225 is removably mounted to the lower surface of the second holder main body 221-2 by magnetic force of the magnets 221-2a and the magnets 225a. The polishing pad 222 is fixed to a lower surface of the pad table 225 by, for example, an adhesive. Disposing the pad table 225 allows facilitating exchanging the polishing pad 222.

As illustrated in FIG. 5, the substrate processing apparatus 1000 includes an abrasion amount measurement member 270 for measuring the amount of abrasion of the polishing pad 222. The abrasion amount measurement member 270 is configured to measure the amount of abrasion of the polishing pad 222 based on a value correlated with a behavior of the elevating mechanism 260 until the polishing pad 222 contacts a reference surface by lowering the polishing pad 222 by the elevating mechanism 260. The abrasion amount measurement member 270 can be constituted of a general computer including an input/output device, an arithmetic device, a storage device, and the like. The following will describe details of the abrasion amount measurement member 270.

### <Abrasion Measurement of Polishing Pad>

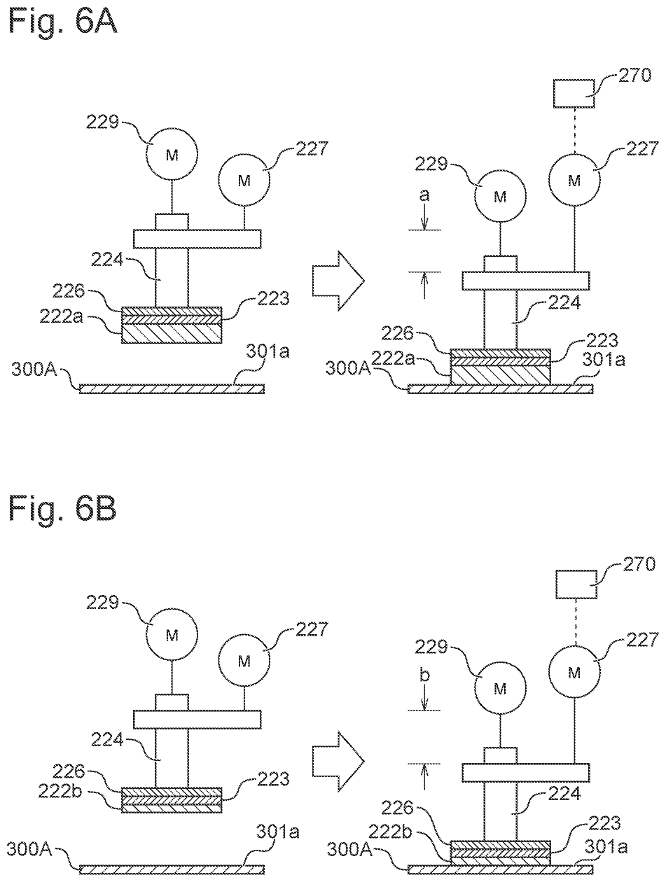

FIG. 6A and FIG. 6B are diagrams schematically illustrating the abrasion measurement of the polishing pad according to a first embodiment. As illustrated in FIG. 6A and FIG. 6B, the abrasion amount measurement member 270 can measure the amount of abrasion of the polishing pad 222 with the support surface (for example, the support surface 301a of the first supporting member 300A) of the supporting member 300 as a reference surface. That is, the abrasion amount measurement member 270 is configured to measure the amount of abrasion of the polishing pad 222 based on information on a height of the pad holder 226 when the pad holder 226 is lowered by the holder elevating mechanism 227 until the polishing pad 222 contacts the support surface 301a of the first supporting member 300A.

Specifically, as illustrated in FIG. 6A, in a state of a polishing pad 222a (for example, a new polishing pad) as a reference being mounted to the pad holder 226, the pad holder 226 is arranged at a search start position. Subsequently, the abrasion amount measurement member 270 measures a lowered amount (a) of the pad holder 226 when the pad holder 226 is lowered by the holder elevating mechanism 227 until the polishing pad 222a contacts the support surface 301a. Note that the holder elevating mechanism 227 is a servomotor incorporating an encoder in this embodiment. The abrasion amount measurement member 270 can detect the contact of the polishing pad 222a with the support surface 301a based on a change in a torque value of the holder elevating mechanism 227. Additionally, the abrasion amount measurement member 270 can measure the lowered amount of the pad holder 226 based on an absolute value of the encoder of the holder elevating mechanism 227. In this embodiment, the description has been made with the new polishing pad as one example of the polishing pad 222a as the reference, but the polishing pad is not limited to this.

Next, as illustrated in FIG. 6B, in a state of a polishing pad 222b as a measurement object (for example, a polishing pad abraded by a polishing process) being mounted to the pad holder 226, the pad holder 226 is arranged at the search start position. Subsequently, the abrasion amount measurement member 270 measures a lowered amount (b) of the pad holder 226 when the pad holder 226 is lowered by the holder elevating mechanism 227 until the polishing pad 222b contacts the support surface 301a. The abrasion amount measurement member 270 is configured to compare the lowered amount (a) of the pad holder 226 with respect to the polishing pad 222a as the reference with the lowered amount (b) of the pad holder 226 with respect to the polishing pad 222b as the measurement object to measure the amount of abrasion of the polishing pad 222b as the measurement object. Specifically, since the lowered amount of the pad holder 226 increases by the abrasion of the polishing pad 222, the lowered amount (b)—the lowered amount (a) is equivalent to the amount of abrasion of the polishing pad 222. Hereinafter, the measurement of the amount of abrasion of the polishing pad 222 by bringing the polishing pad 222 into contact with the reference surface is referred to as “pad search” as necessary. Note that in the example illustrated in FIG. 6, the example in which the amount of abrasion of the polishing pad 222 is measured based on the comparison between the lowered amounts of the pad holders 226 has been described, but the measurement is not limited to this. The abrasion amount measurement member 270, for example, can measure the amount of abrasion of the polishing pad 222 based on the comparison between information on the height of the pad holder 226 when the polishing pad 222a as the reference contacts the support surface 301a and information on the height of the pad holder 226 when the polishing pad 222b as the measurement object contacts the support surface 301a.

Note that, in this embodiment, an example in which the abrasion amount measurement member 270 uses the support surface of the supporting member 300 as the reference surface has been described, but the measurement is not limited to this. For example, the amount of abrasion of the polishing pad 222 can be measured with the surface to be polished of the substrate WF as the reference surface. Additionally, after the abrasion amount measurement member 270 lowers the pad holder 226 from the search start position at a first speed, the abrasion amount measurement member 270 may switch the first speed to a second speed lower than the first speed and lower the pad holder 226 to bring the polishing pad 222 to be in contact with the support surface 301a. Bringing the polishing pad 222 in contact with the support surface 301a at low speed allows reducing application of an excessive load on the holder elevating mechanism 227. The abrasion amount measurement member 270 can perform the pad search in a plurality of states in which a rotation angle of the pad holder 226 is differentiated by the pad rotation mechanism 229 and measure the amount of abrasion of the polishing pad 222 based on the average value of a plurality of times of pad search. This suppresses incorrect measurement of the amount of abrasion of the polishing pad 222 caused by, for example, an overlap of ups and downs of the polishing pad 222 and the support surface 301a, ensuring measuring the amount of abrasion of the polishing pad 222 more accurately.

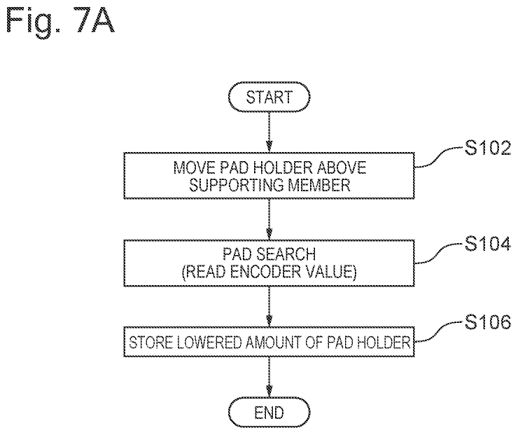

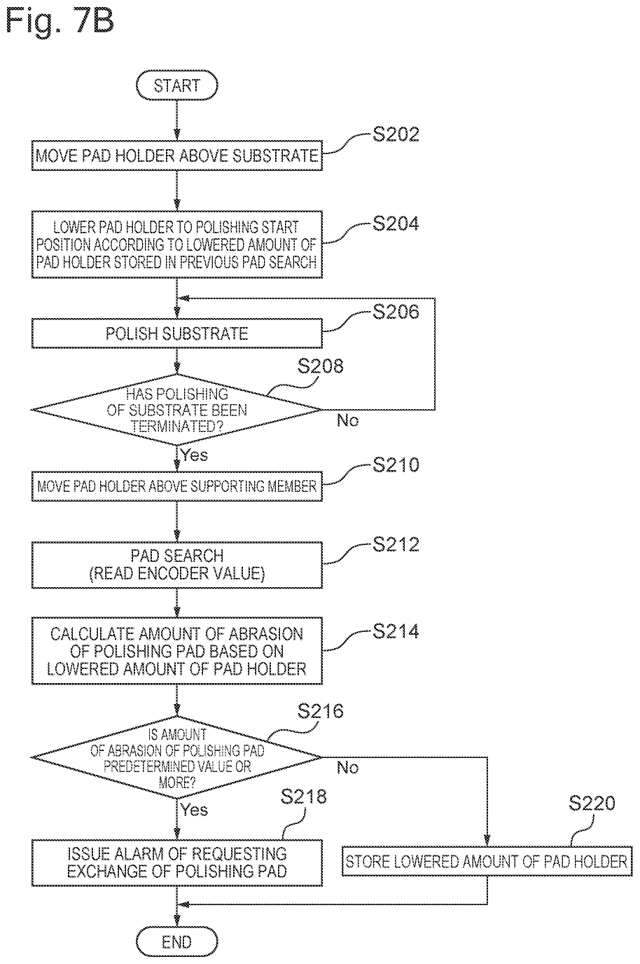

Next, a procedure of the substrate processing method according to a first embodiment will be described. FIG. 7A and FIG. 7B are flowcharts depicting the abrasion measurement of the polishing pad according to the first embodiment. As illustrated in FIG. 7A, the substrate processing method first moves the pad holder 226 to the search start position on the supporting member 300A in a state of the polishing pad 222a as the reference being mounted to the pad holder 226 (Step 102). Subsequently, the substrate processing method performs the pad search (Step 104). Specifically, as described above, the pad holder 226 is lowered until the polishing pad 222a contacts the support surface 301a, and the lowered amount (a) of the pad holder 226 is measured based on the absolute value of the encoder of the holder elevating mechanism 227. Subsequently, the substrate processing method stores the lowered amount (a) of the pad holder 226 at this time in the storage device (Step 106).

On the other hand, to polish the substrate and measure the amount of abrasion of the polishing pad 222, as illustrated in FIG. 7B, the substrate processing method moves the pad holder 226 above the substrate WF in the state of the polishing pad 222b as the measurement object being mounted to the pad holder 226 (Step 202). Subsequently, the substrate processing method lowers the pad holder 226 to a polishing start position according to the lowered amount of the pad holder 226 stored in Step 106 or Step 220 described below (Step 204). At Step 204, when the pad search at Step 212 has not been performed on the polishing pad 222b as the measurement object, the pad holder 226 is lowered according to the lowered amount of the pad holder 226 stored in Step 106. On the other hand, at Step 204, after the pad search at Step 212 has been performed on the polishing pad 222b as the measurement object, the pad holder 226 is lowered according to the lowered amount of the pad holder 226 stored at Step 220 in the latest pad search. This is because to keep a distance between the surface to be polished of the substrate WF and the polishing surface of the polishing pad 222b when the polishing process is performed constant. That is, before starting the polishing, the inside of the air bag 223 is in a contracted state by vacuum drawing. At Step 204, the height of the pad holder 226 is controlled such that the distance between the polishing surface of the polishing pad 222 and the surface to be polished of the substrate WF becomes constant (not in contact) according to the amount of abrasion of the polishing pad 222 measured by the abrasion amount measurement member 270. Specifically, since the polishing pad 222b abrades by the polishing process, by adjusting the height position of the pad holder 226 by the abrasion, the distance between the surface to be polished of the substrate WF and the polishing surface of the polishing pad 222b at the start of polishing can be kept constant. Consequently, expansion of the air bag 223 allows keeping a force of pressing the polishing pad 222b against the surface to be polished of the substrate WF constant, and thus the substrate WF can be uniformly polished.

Subsequently, the substrate processing method performs the polishing process of the substrate WF (Step 206). Specifically, the substrate processing method supplies polishing liquid (slurry) from the nozzle 228 and rotates the pad holder 226 and the table 100. Furthermore, the substrate processing method polishes the substrate WF by supplying a fluid (such as air) to the air bag 223 to swing the pad holder 226 while pressing the polishing pad 222b against the substrate WF. As described above, after the substrate processing method performs height control of the pad holder 226 at the polishing start position according to the amount of abrasion of the polishing pad 222, the substrate processing method causes the fluid to flow in the air bag 223 to bulge the air bag 223, and presses the polishing pad 222 against the substrate WF. Accordingly, even when the polishing pad 222 is worn, since the bulge of the air bag 223 can be kept constant, the substrate WF can be pressed at always same pressure. The substrate processing method determines whether or not the polishing of the substrate WF is terminated (Step 208), and repeats the polishing process until the polishing of the substrate WF terminates.

On the other hand, when it is determined that the polishing of the substrate WF is terminated (Step 208, Yes), the substrate processing method moves the pad holder 226 to the search start position on the supporting member 300A (Step 210). Subsequently, the substrate processing method performs the pad search (Step 212). Step 212 specifically includes a lowering step of lowering the pad holder 226 until the polishing pad 222b contacts the support surface 301a in a state of the air bag 223 being contracted by vacuum drawing as described above. Step 212 includes a measuring step of measuring the lowered amount (b) of the pad holder 226 until the polishing pad 222 contacts the support surface 301a based on the absolute value of the encoder of the holder elevating mechanism 227. The measuring step measures the amount of abrasion of the polishing pad 222b based on the lowered amount (b) of the pad holder 226 (Step 214). Specifically, the measuring step compares the lowered amount (a) of the pad holder 226 with respect to the polishing pad 222a as the reference with the lowered amount (b) of the pad holder 226 with respect to the polishing pad 222b as the measurement object to measure the amount of abrasion of the polishing pad 222b.

Subsequently, the substrate processing method determines whether or not the amount of abrasion of the polishing pad 222b is a predetermined value or more (Step 216). When the amount of abrasion of the polishing pad 222b is the predetermined value or more (Step 216, Yes), the substrate processing method issues an alarm of requesting exchange of the polishing pad 222b (Step 218). On the other hand, when the amount of abrasion of the polishing pad 222b is less than the predetermined value (Step 216, No), the substrate processing method stores the lowered amount (b) of the pad holder 226 in the storage device (Step 220).

According to this embodiment, since the abrasion amount measurement member 270 performs the pad search using a configuration that the substrate processing apparatus 1000 originally includes for the polishing process, a special configuration for measurement of the amount of abrasion need not be arranged. Consequently, the amount of abrasion of the polishing pad can be measured with the simple structure. Additionally, according to this embodiment, since the pad search is performed with the hard and flat support surface of the supporting member 300 (for example, the support surface 301a of the first supporting member 300A) as the reference surface, the amount of abrasion of the polishing pad 222 can be accurately measured. According to this embodiment, since the pad holder 226 is moved to the polishing start position according to the amount of abrasion of the polishing pad 222 and the polishing process is performed, the distance between the surface to be polished of the substrate WF and the polishing surface of the polishing pad 222b at the start of polishing can be kept constant. As a result, since the force of pressing the polishing pad 222b against the surface to be polished of the substrate WF by the expansion of the air bag 223 can be kept constant, the substrate WF can be uniformly polished. Note that, in this embodiment, as illustrated in FIG. 7A, the example in which the pad search is performed on the polishing pad 222a as the reference has been described, but the pad search is not limited to this. For example, as long as the distance between the polishing pad 222a as the reference and the reference surface is known in a state of the pad holder 226 being arranged at the search start position, the pad search depicted in FIG. 7A need not be performed.

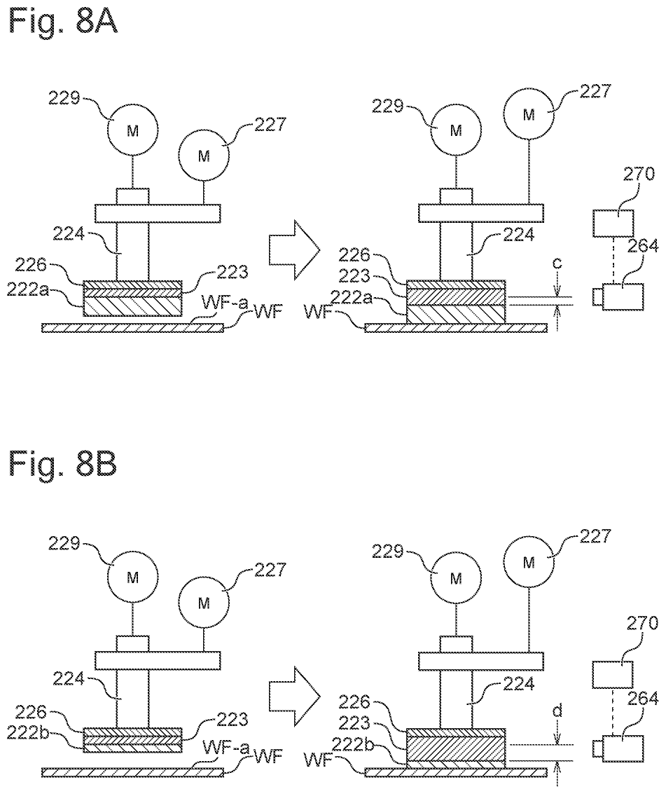

Next, abrasion measurement of the polishing pad of a second embodiment will be described. FIG. 8A and FIG. 8B are diagrams schematically illustrating the abrasion measurement of the polishing pad according to the second embodiment. As illustrated in FIG. 8A and FIG. 8B, the abrasion amount measurement member 270 includes an imaging member (camera) 264 for imaging the air bag 223. The abrasion amount measurement member 270 is configured to measure an amount of bulge of the air bag 223 until the polishing pad 222 contacts the reference surface (for example, a surface to be polished WF-a of the substrate WF) based on the image taken by the imaging member 264, and measure the amount of abrasion of the polishing pad 222 based on the measured amount of bulge of the air bag 223.

Specifically, as illustrated in FIG. 8A, in the state of the polishing pad 222a as the reference (for example, a new polishing pad) being mounted to the pad holder 226, the pad holder 226 is arranged at the search start position. At this time, the air bag 223 is contracted by vacuum drawing. Note that when the search start position is too high, even when the air bag 223 is maximally expanded, the polishing pad 222a does not contact the surface to be polished WF-a of the substrate WF. Accordingly, the search start position in FIG. 8A is set according to an allowable expansion amount of the air bag 223 such that the polishing pad 222a can contact the surface to be polished WF-a of the substrate WF. Subsequently, the abrasion amount measurement member 270 supplies the air bag 223 with the fluid to bulge the air bag 223. Subsequently, the abrasion amount measurement member 270 measures an amount of bulge (c) of the air bag 223 until the polishing pad 222a contacts the surface to be polished WF-a of the substrate WF based on the image acquired by the imaging member 264. Note that the abrasion amount measurement member 270 can detect the contact of the polishing pad 222a with the support surface 301a based on a change in an amount of inflow of the fluid to the air bag 223 or the change in the torque value of the holder elevating mechanism 227.

Next, as illustrated in FIG. 8B, in a state of the polishing pad 222b as the measurement object (for example, the polishing pad abraded by the polishing process) being mounted to the pad holder 226, the pad holder 226 is arranged at the search start position. Subsequently, the abrasion amount measurement member 270 supplies the air bag 223 with the fluid to bulge the air bag 223. Subsequently, the abrasion amount measurement member 270 measures an amount of bulge (d) of the air bag 223 until the polishing pad 222a contacts the surface to be polished WF-a of the substrate WF based on the image acquired by the imaging member 264. The abrasion amount measurement member 270 is configured to compare the amount of bulge (c) of the air bag 223 with respect to the polishing pad 222a as the reference with the amount of bulge (d) of the air bag 223 with respect to the polishing pad 222b as the measurement object to measure the amount of abrasion of the polishing pad 222b as the measurement object. Specifically, since the amount of bulge of the air bag 223 increases by the abrasion of the polishing pad 222, the amount of bulge (d)—the amount of bulge (c) is equivalent to the amount of abrasion of the polishing pad 222.

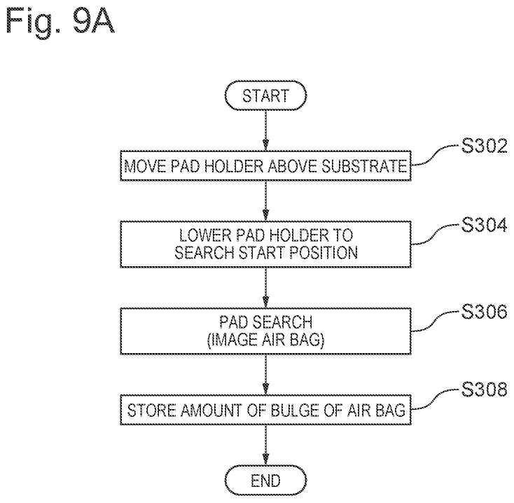

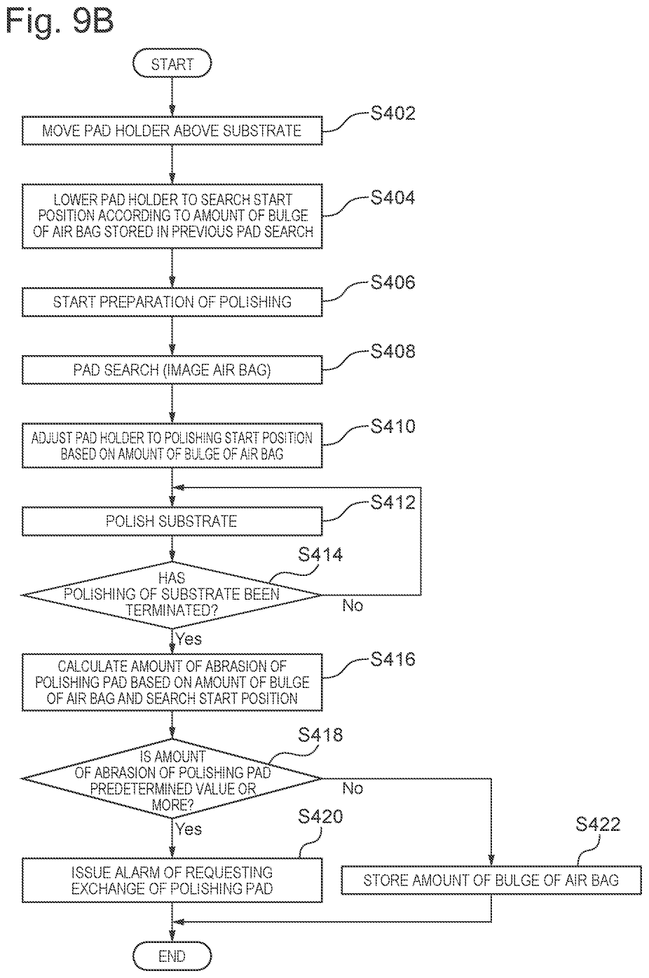

Next, a procedure of the substrate processing method according to the second embodiment will be described. FIG. 9A and FIG. 9B are flowcharts depicting the abrasion measurement of the polishing pad according to the second embodiment. As illustrated in FIG. 9A, the substrate processing method first moves the pad holder 226 above the substrate WF in a state of the polishing pad 222a as the reference being mounted to the pad holder 226 (Step 302). Subsequently, the substrate processing method lowers the pad holder 226 to the search start position (Step 304). Subsequently, the substrate processing method performs the pad search (Step 306). Specifically, as described above, the air bag 223 is expanded until the polishing pad 222a contacts the surface to be polished WF-a of the substrate WF, and the amount of bulge (c) of the air bag 223 is measured based on the image acquired by the imaging member 264. Subsequently, the substrate processing method stores the amount of bulge (c) of the air bag 223 at this time in the storage device (Step 308).

On the other hand, to polish the substrate and measure the amount of abrasion of the polishing pad 222, as illustrated in FIG. 9B, the substrate processing method moves the pad holder 226 above the substrate WF in the state of the polishing pad 222b as the measurement object being mounted to the pad holder 226 (Step 402). Subsequently, the substrate processing method lowers the pad holder 226 to the search start position according to the amount of bulge of the air bag 223 stored in Step 308 or Step 422 described below (Step 404). At Step 404, when the pad search at Step 408 has not been performed on the polishing pad 222b as the measurement object, the pad holder 226 is lowered according to the amount of bulge of the air bag 223 stored in Step 308. On the other hand, at Step 404, after the pad search at Step 408 has been performed on the polishing pad 222b as the measurement object, the pad holder 226 is lowered according to the amount of bulge of the air bag 223 stored at Step 308 in the latest pad search.

By thus lowering the pad holder 226 to the search start position according to the amount of bulge of the air bag 223, the following pad search and polishing process can be accurately performed irrespective of the amount of abrasion of the polishing pad 222. That is, it is also considered that the following pad search and polishing process are performed in a state of the pad holder 226 being arranged at a fixed predetermined height position (absolute value) every time. In this case, when the amount of abrasion of the polishing pad 222 increases with respect to the allowable expansion amount of the air bag 223, even when the air bag 223 is maximally expanded, the polishing pad 222b possibly does not contact the surface to be polished WF-a of the substrate WF. Then, the following pad search and polishing process cannot be performed. In contrast to this, in this embodiment, before the pad search and the polishing process are performed, the pad holder 226 is lowered according to the amount of bulge of the air bag 223 stored in Step 308 or Step 422. Therefore, even when the amount of abrasion of the polishing pad 222 increases with respect to the allowable expansion amount of the air bag 223, the pad search and the polishing process can be accurately performed. Note that when the allowable expansion amount of the air bag 223 is sufficiently large with respect to the amount of abrasion of the polishing pad 222, the concern as described above does not occur, and therefore the pad holder 226 may be arranged at the predetermined height position at Step 404.

Subsequently, the substrate processing method starts preparation of the polishing process of the substrate WF (Step 406). Specifically, the substrate processing method supplies polishing liquid (slurry) from the nozzle 228 and rotates the pad holder 226 and the table 100. Subsequently, the substrate processing method performs the pad search (Step 408). Step 408 specifically includes a lowering step of flowing a fluid in the air bag 223 until the polishing pad 222b contacts the surface to be polished WF-a of the substrate WF. Additionally, Step 408 includes a measuring step of imaging the air bag 223 by the imaging member 264 while expanding the air bag 223 and measuring the amount of bulge (d) of the air bag 223 based on the taken image.

Subsequently, the substrate processing method adjusts the pad holder 226 to the polishing start position based on the amount of bulge (d) of the air bag 223 (Step 410). This is because to keep the amount of bulge of the air bag 223 when the polishing process is performed constant. That is, since the polishing pad 222b abrades by the polishing process, adjusting the position of the pad holder 226 by the abrasion allows keeping the amount of bulge of the air bag 223 constant. Consequently, expansion of the air bag 223 allows keeping a force of pressing the polishing pad 222b against the surface to be polished WF-a of the substrate WF constant, and thus the substrate WF can be uniformly polished. Subsequently, the substrate processing method swings the pad holder 226 while pressing the polishing pad 222b against the substrate WF to polish the substrate WF (Step 412). The substrate processing method determines whether or not the polishing of the substrate WF is terminated (Step 414), and repeats the polishing process until the polishing of the substrate WF terminates.

On the other hand, when it is determined that the polishing of the substrate WF terminates (Step 414, Yes), the substrate processing method measures the amount of abrasion of the polishing pad 222b based on the amount of bulge (d) of the air bag 223 and the search start position (measuring step 416). Specifically, the measuring step 416 compares the amount of bulge (c) of the air bag 223 with respect to the polishing pad 222a as the reference with the amount of bulge (d) of the air bag 223 with respect to the polishing pad 222b as the measurement object to measure the amount of abrasion of the polishing pad 222b.

Subsequently, the substrate processing method determines whether or not the amount of abrasion of the polishing pad 222b is a predetermined value or more (Step 418). When the amount of abrasion of the polishing pad 222b is the predetermined value or more (Step 418, Yes), the substrate processing method issues an alarm of requesting exchange of the polishing pad 222b (Step 420). On the other hand, when the amount of abrasion of the polishing pad 222b is less than the predetermined value (Step 418, No), the substrate processing method stores the amount of bulge (d) of the air bag 223 in the storage device (Step 422).

According to this embodiment, since the abrasion amount measurement member 270 performs the pad search using a configuration that the substrate processing apparatus 1000 originally includes for the polishing process, a special configuration for measurement of the amount of abrasion need not be arranged. Consequently, the amount of abrasion of the polishing pad can be measured with the simple structure. According to this embodiment, since the pad holder 226 is moved to the polishing start position according to the amount of abrasion of the polishing pad 222 and the polishing process is performed, the amount of bulge of the air bag 223 at the start of polishing can be kept constant. As a result, since the force of pressing the polishing pad 222b against the surface to be polished of the substrate WF by the expansion of the air bag 223 can be kept constant, the substrate WF can be uniformly polished.

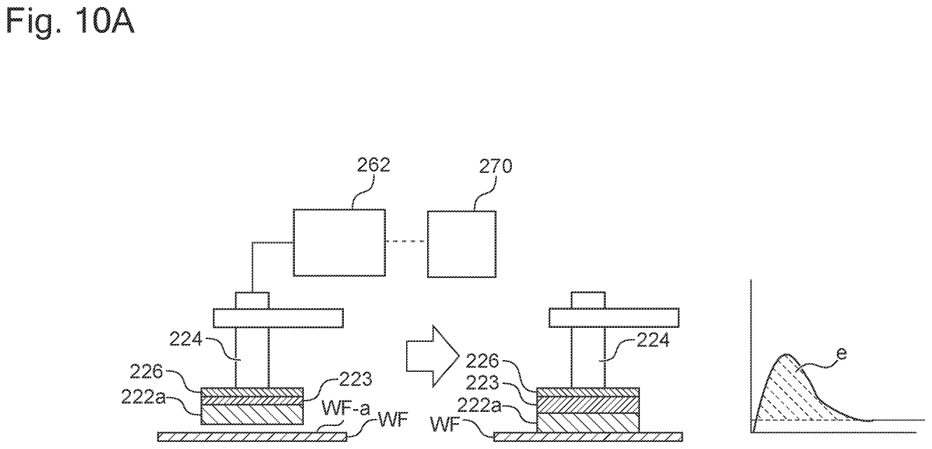

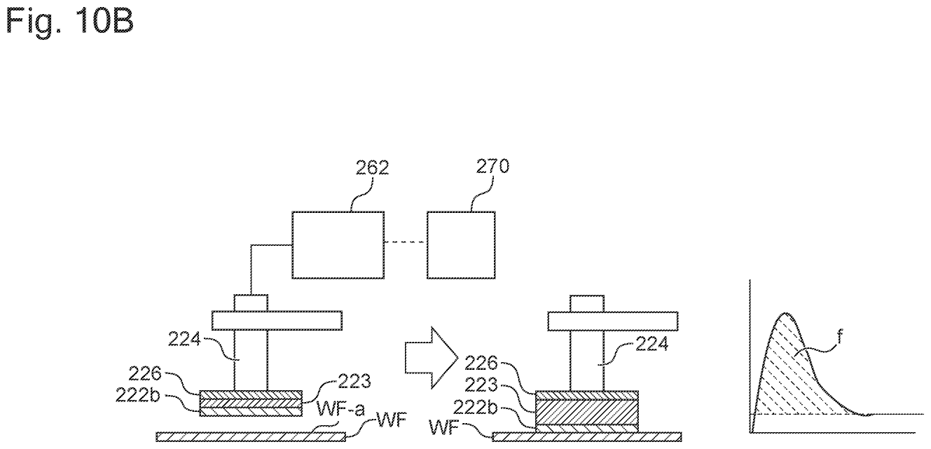

Next, the abrasion measurement of the polishing pad of a third embodiment will be described. FIG. 10A and FIG. 10B are diagrams schematically illustrating the abrasion measurement of the polishing pad according to the third embodiment. As illustrated in FIG. 10A and FIG. 10B, the abrasion amount measurement member 270 includes a flowmeter 262 for ensuring measurement of the amount of inflow of the fluid to the air bag 223. The abrasion amount measurement member 270 is configured to measure the amount of inflow of the fluid to the air bag 223 until the polishing pad 222 contacts the reference surface (for example, the surface to be polished WF-a of the substrate WF) by the flowmeter 262 and measure the amount of abrasion of the polishing pad 222 based on the measured amount of inflow of the fluid.

Specifically, as illustrated in FIG. 10A, in the state of the polishing pad 222a as the reference (for example, a new polishing pad) being mounted to the pad holder 226, the pad holder 226 is arranged at the search start position. At this time, the air bag 223 is contracted by vacuum drawing. Note that when the search start position is too high, even when the air bag 223 is maximally expanded, the polishing pad 222a does not contact the surface to be polished WF-a of the substrate WF. Accordingly, the search start position in FIG. 10A is set according to the allowable expansion amount of the air bag 223 such that the polishing pad 222a can contact the surface to be polished WF-a of the substrate WF. Subsequently, the abrasion amount measurement member 270 supplies the air bag 223 with the fluid to bulge the air bag 223. Subsequently, the abrasion amount measurement member 270 measures an amount of inflow (e) of the fluid to the air bag 223 until the polishing pad 222a contacts the surface to be polished WF-a of the substrate WF.

Next, as illustrated in FIG. 10B, in a state of the polishing pad 222b as the measurement object (for example, the polishing pad abraded by the polishing process) being mounted to the pad holder 226, the pad holder 226 is arranged at the search start position. Subsequently, the abrasion amount measurement member 270 supplies the air bag 223 with the fluid to bulge the air bag 223. Subsequently, the abrasion amount measurement member 270 measures an amount of inflow (f) of the fluid to the air bag 223 until the polishing pad 222a contacts the surface to be polished WF-a of the substrate WF. The abrasion amount measurement member 270 is configured to compare the amount of inflow (e) of the fluid to the air bag 223 with respect to the polishing pad 222a as the reference with the amount of inflow (f) of the fluid to the air bag 223 with respect to the polishing pad 222b as the measurement object to measure the amount of abrasion of the polishing pad 222b as the measurement object. Specifically, since the amount of inflow (f) of the fluid to the air bag 223 increases by the abrasion of the polishing pad 222, the amount correlated with the amount of inflow (f)—the amount of inflow (e) is equivalent to the amount of abrasion of the polishing pad 222. That is, since the correlation between the amount of inflow of the fluid to the air bag 223 and the amount of abrasion (thickness) of the polishing pad 222 is preliminarily acquired, when the amount of inflow (f)—the amount of inflow (e) is found, the amount of abrasion of the polishing pad 222 can be obtained.

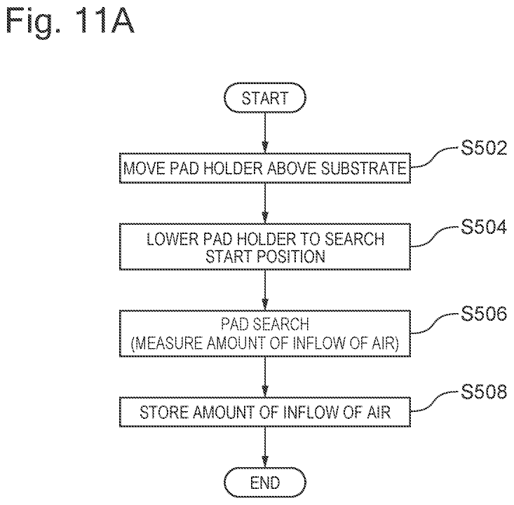

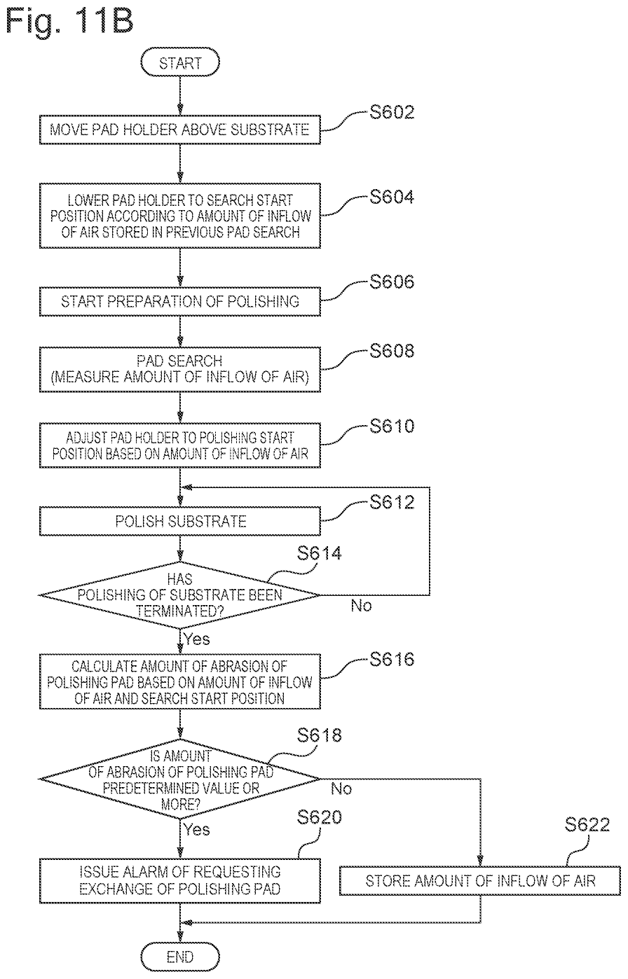

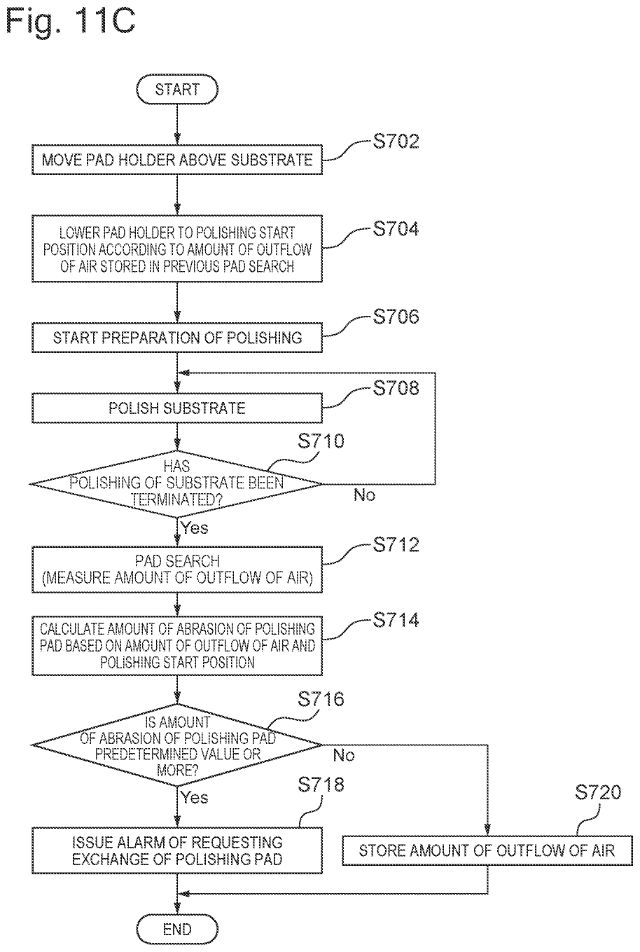

Next, a procedure of the substrate processing method according to the third embodiment will be described. FIG. 11A and FIG. 11B are flowcharts depicting the abrasion measurement of the polishing pad according to the third embodiment. As illustrated in FIG. 11A, the substrate processing method first moves the pad holder 226 above the substrate WF in a state of the polishing pad 222a as the reference being mounted to the pad holder 226 (Step 502). Subsequently, the substrate processing method lowers the pad holder 226 to the search start position (Step 504). Subsequently, the substrate processing method performs the pad search (Step 506). Specifically, as described above, the air bag 223 is expanded until the polishing pad 222a contacts the surface to be polished WF-a of the substrate WF, and the amount of inflow (e) of the fluid to the air bag 223 is measured by the flowmeter 262. Subsequently, the substrate processing method stores the amount of inflow (e) of the fluid to the air bag 223 at this time in the storage device (Step 508).

On the other hand, to polish the substrate and measure the amount of abrasion of the polishing pad 222, as illustrated in FIG. 11B, the substrate processing method moves the pad holder 226 above the substrate WF in the state of the polishing pad 222b as the measurement object being mounted to the pad holder 226 (Step 602). Subsequently, the substrate processing method lowers the pad holder 226 to the search start position according to the amount of inflow of the fluid to the air bag 223 stored in Step 508 or Step 622 described below (Step 604). At Step 604, when the pad search at Step 608 has not been performed on the polishing pad 222b as the measurement object, the pad holder 226 is lowered according to the amount of inflow of the fluid to the air bag 223 stored in Step 508. On the other hand, at Step 604, after the pad search at Step 608 has been performed on the polishing pad 222b as the measurement object, the pad holder 226 is lowered according to the amount of inflow of the fluid to the air bag 223 stored at Step 608 in the latest pad search. By lowering the pad holder 226 to the search start position according to the amount of inflow of the fluid to the air bag 223, similarly to the second embodiment, even when the amount of abrasion of the polishing pad 222 increases with respect to the allowable expansion amount of the air bag 223, the pad search and the polishing process can be accurately performed.

Subsequently, the substrate processing method starts preparation of the polishing process of the substrate WF (Step 606). Specifically, the substrate processing method supplies polishing liquid (slurry) from the nozzle 228 and rotates the pad holder 226 and the table 100. Subsequently, the substrate processing method performs the pad search (Step 608). Step 608 specifically includes a lowering step of flowing a fluid in the air bag 223 until the polishing pad 222b contacts the surface to be polished WF-a of the substrate WF. Additionally, Step 608 includes a measuring step of measuring the amount of inflow (f) of the fluid to the air bag 223 by the flowmeter 262 while expanding the air bag 223.

Subsequently, the substrate processing method adjusts the pad holder 226 to the polishing start position based on the amount of inflow (f) of the fluid to the air bag 223 (Step 610). The substrate processing method, for example, can adjust the height position of the pad holder 226 such that the amount of inflow (f) of the fluid to the air bag 223 becomes the preset predetermined amount of inflow. This is because to keep the amount of bulge of the air bag 223 when the polishing process is performed constant. That is, since the polishing pad 222b abrades by the polishing process, adjusting the position of the pad holder 226 by the abrasion allows keeping the amount of bulge of the air bag 223 constant. Consequently, expansion of the air bag 223 allows keeping a force of pressing the polishing pad 222b against the surface to be polished WF-a of the substrate WF constant, and thus the substrate WF can be uniformly polished. Subsequently, the substrate processing method swings the pad holder 226 while pressing the polishing pad 222b against the substrate WF to polish the substrate WF (Step 612). The substrate processing method determines whether or not the polishing of the substrate WF is terminated (Step 614), and repeats the polishing process until the polishing of the substrate WF terminates.

On the other hand, when it is determined that the polishing of the substrate WF terminates (Step 614, Yes), the substrate processing method measures the amount of abrasion of the polishing pad 222b based on the amount of inflow (f) of the fluid to the air bag 223 and the search start position (measuring step 616). Specifically, the measuring step 616 compares the amount of inflow (e) of the fluid to the air bag 223 with respect to the polishing pad 222a as the reference with the amount of inflow (f) of the fluid to the air bag 223 with respect to the polishing pad 222b as the measurement object to measure the amount of abrasion of the polishing pad 222b.

Subsequently, the substrate processing method determines whether or not the amount of abrasion of the polishing pad 222b is a predetermined value or more (Step 618). When the amount of abrasion of the polishing pad 222b is the predetermined value or more (Step 618, Yes), the substrate processing method issues an alarm of requesting exchange of the polishing pad 222b (Step 620). On the other hand, when the amount of abrasion of the polishing pad 222b is less than the predetermined value (Step 618, No), the substrate processing method stores the amount of inflow (f) of the fluid to the air bag 223 in the storage device (Step 622).

According to this embodiment, since the abrasion amount measurement member 270 performs the pad search using a configuration that the substrate processing apparatus 1000 originally includes for the polishing process, a special configuration for measurement of the amount of abrasion need not be arranged. Consequently, the amount of abrasion of the polishing pad can be measured with the simple structure. According to this embodiment, since the pad holder 226 is moved to the polishing start position according to the amount of abrasion of the polishing pad 222 and the polishing process is performed, the amount of bulge of the air bag 223 at the start of polishing can be kept constant. As a result, since the force of pressing the polishing pad 222b against the surface to be polished of the substrate WF by the expansion of the air bag 223 can be kept constant, the substrate WF can be uniformly polished.

Note that, in the third embodiment, the example in which the amount of abrasion of the polishing pad 222 is measured based on the amount of inflow of the fluid to the air bag 223 with respect to the polishing pad 222b as the measurement object has been described, but the measurement is not limited to this. The abrasion amount measurement member 270 can also measure the amount of abrasion of the polishing pad 222 based on an amount of outflow of the fluid from the air bag 223. In this case, the flowmeter 262 is configured to ensure measuring the amount of outflow of the fluid from the air bag 223.

FIG. 11C is a flowchart depicting abrasion measurement of a polishing pad according to a modification of the third embodiment. To polish the substrate and measure the amount of abrasion of the polishing pad 222, as depicted in FIG. 11C, the substrate processing method moves the pad holder 226 above the substrate WF in the state of the polishing pad 222b as the measurement object being mounted to the pad holder 226 (Step 702). Subsequently, the substrate processing method lowers the pad holder 226 to the polishing start position according to the amount of outflow of the fluid from the air bag 223 stored when the previous pad search has been performed (Step 704).

Subsequently, the substrate processing method starts preparation of the polishing process of the substrate WF (Step 706). Specifically, the substrate processing method supplies polishing liquid (slurry) from the nozzle 228 and rotates the pad holder 226 and the table 100. Subsequently, the substrate processing method applies a pressure to the air bag 223 and swings the pad holder 226 while pressing the polishing pad 222b against the substrate WF to polish the substrate WF (Step 708). The substrate processing method determines whether or not the polishing of the substrate WF is terminated (Step 710), and repeats the polishing process until the polishing of the substrate WF terminates.

On the other hand, when it is determined that the polishing of the substrate WF terminates (Step 710, Yes), the substrate processing method performs the pad search (Step 712). Specifically, the substrate processing method measures an amount of outflow (g) of the fluid from the air bag 223 by the flowmeter 262 while contracting the air bag 223 from the state of the polishing pad 222b contacting the surface to be polished of the substrate WF.

Subsequently, the substrate processing method measures the amount of abrasion of the polishing pad 222b based on the amount of outflow (g) of the fluid from the air bag 223 and the polishing start position (Step 714). Specifically, the substrate processing method compares the amount of inflow (e) of the fluid to the air bag 223 with respect to the polishing pad 222a as the reference with the amount of outflow (g) of the fluid from the air bag 223 with respect to the polishing pad 222b as the measurement object to measure the amount of abrasion of the polishing pad 222b.

Subsequently, the substrate processing method determines whether or not the amount of abrasion of the polishing pad 222b is a predetermined value or more (Step 716). When the amount of abrasion of the polishing pad 222b is the predetermined value or more (Step 716, Yes), the substrate processing method issues an alarm of requesting exchange of the polishing pad 222b (Step 718). On the other hand, when the amount of abrasion of the polishing pad 222b is less than the predetermined value (Step 716, No), the substrate processing method stores the amount of outflow (g) of the fluid from the air bag 223 in the storage device (Step 720).

Note that in the above-described first to third embodiments, the pad search may be performed each time one substrate WF is polished or may be performed each time the predetermined number of substrates WF are polished.

The embodiments of the present invention have been described above in order to facilitate understanding of the present invention without limiting the present invention. The present invention can be changed or improved without departing from the gist thereof, and of course, the equivalents of the present invention are included in the present invention. It is possible to arbitrarily combine or omit respective components according to claims and description in a range in which at least a part of the above-described problems can be solved, or a range in which at least a part of the effects can be exhibited.

This application discloses, as one embodiment, a substrate processing apparatus that includes a table, a pad holder, an elevating mechanism, and an abrasion amount measurement member. The table is for supporting a substrate with a surface to be polished facing upward. The pad holder is for holding a polishing pad for polishing the substrate supported by the table. The elevating mechanism is for moving up and down the polishing pad held to the pad holder. The abrasion amount measurement member is configured to lower the polishing pad by the elevating mechanism and measure an amount of abrasion of the polishing pad based on a value correlated with a behavior of the elevating mechanism until the polishing pad contacts a reference surface.

This application further discloses, as one embodiment, a substrate processing apparatus that further includes a swing mechanism and a supporting member. The swing mechanism is for swinging the pad holder in a radial direction of the substrate. The supporting member has a support surface for supporting the polishing pad swung to an outside of the table by the swing mechanism. The elevating mechanism includes a holder elevating mechanism for moving up and down the pad holder. The reference surface is the support surface of the supporting member. The abrasion amount measurement member is configured to measure the amount of abrasion of the polishing pad based on information on a height of the pad holder when the pad holder is lowered by the holder elevating mechanism until the polishing pad contacts the support surface of the supporting member.

This application further discloses, as one embodiment, the following substrate processing apparatus. The elevating mechanism includes a holder elevating mechanism for moving up and down the pad holder. The reference surface is the surface to be polished of the substrate. The abrasion amount measurement member is configured to measure the amount of abrasion of the polishing pad based on information on a height of the pad holder when the pad holder is lowered by the holder elevating mechanism until the polishing pad contacts the surface to be polished of the substrate.

This application further discloses, as one embodiment, the following substrate processing apparatus. The abrasion amount measurement member is configured to compare information on a height of the pad holder with respect to a polishing pad as a reference with information on a height of the pad holder with respect to a polishing pad as a measurement object to measure the amount of abrasion of the polishing pad as the measurement object.

This application further discloses, as one embodiment, the following substrate processing apparatus. The elevating mechanism includes a bag member mounted to the pad holder. The bag member is for moving up and down the polishing pad by expansion and contraction caused by inflow and outflow of a fluid. The abrasion amount measurement member includes an imaging member for imaging the bag member. The abrasion amount measurement member is configured to measure an amount of bulge of the bag member until the polishing pad contacts the reference surface based on an image taken by the imaging member to measure the amount of abrasion of the polishing pad based on the measured amount of bulge of the bag member.

This application further discloses, as one embodiment, the following substrate processing apparatus. The abrasion amount measurement member is configured to compare an amount of bulge of the bag member with respect to a polishing pad as a reference with an amount of bulge of the bag member with respect to a polishing pad as a measurement object to measure the amount of abrasion of the polishing pad as the measurement object.

This application further discloses, as one embodiment, the following substrate processing apparatus. The elevating mechanism includes a bag member mounted to the pad holder. The bag member is for moving up and down the polishing pad by expansion and contraction caused by inflow and outflow of a fluid. The abrasion amount measurement member includes a flowmeter configured to measure an amount of inflow of the fluid to the bag member. The abrasion amount measurement member is configured to measure the amount of abrasion of the polishing pad based on the amount of inflow of the fluid to the bag member until the polishing pad contacts the reference surface.

This application further discloses, as one embodiment, the following substrate processing apparatus. The abrasion amount measurement member is configured to compare an amount of inflow of a fluid to the bag member with respect to a polishing pad as a reference with an amount of inflow of a fluid to the bag member with respect to a polishing pad as a measurement object to measure the amount of abrasion of the polishing pad as the measurement object.

This application further discloses, as one embodiment, the following substrate processing apparatus. The abrasion amount measurement member is further configured to measure the amount of abrasion of the polishing pad based on a value correlated with a behavior of the elevating mechanism when the polishing pad rises from a state of the polishing pad contacting the reference surface by the elevating mechanism. The elevating mechanism includes a bag member mounted to the pad holder. The bag member is for moving up and down the polishing pad by expansion and contraction caused by inflow and outflow of a fluid. The abrasion amount measurement member includes a flowmeter configured to measure an amount of outflow of the fluid from the bag member. The abrasion amount measurement member is configured to measure the amount of abrasion of the polishing pad based on an amount of outflow of the fluid when the bag member is contracted from the state of the polishing pad contacting the reference surface.

This application further discloses, as one embodiment, the following substrate processing apparatus. The abrasion amount measurement member is configured to compare an amount of outflow of a fluid from the bag member with respect to a polishing pad as a reference with an amount of outflow of a fluid from the bag member with respect to a polishing pad as a measurement object to measure the amount of abrasion of the polishing pad as the measurement object.

This application further discloses, as one embodiment, a substrate processing method that includes: a lowering step of lowering a polishing pad for polishing a substrate supported to a table with a surface to be polished facing upward by an elevating mechanism until the polishing pad contacts a reference surface; and a measuring step of measuring an amount of abrasion of the polishing pad based on a value correlated with a behavior of the elevating mechanism until the polishing pad contacts the reference surface by the lowering step.

This application further discloses, as one embodiment, the following substrate processing method. The elevating mechanism includes a holder elevating mechanism for moving up and down a pad holder for holding the polishing pad. The reference surface is a support surface of a supporting member for supporting the polishing pad swung to an outside of the table. The lowering step is configured to lower the pad holder by the holder elevating mechanism until the polishing pad contacts the support surface. The measuring step is configured to measure the amount of abrasion of the polishing pad based on information on a height of the pad holder when the pad holder is lowered by the holder elevating mechanism until the polishing pad contacts the support surface.

This application further discloses, as one embodiment, the following substrate processing method. The elevating mechanism includes a holder elevating mechanism for moving up and down a pad holder for holding the polishing pad. The reference surface is the surface to be polished of the substrate. The lowering step is configured to lower the pad holder by the holder elevating mechanism until the polishing pad contacts the surface to be polished of the substrate. The measuring step is configured to measure the amount of abrasion of the polishing pad based on information on a height of the pad holder when the pad holder is lowered by the holder elevating mechanism until the polishing pad contacts the surface to be polished of the substrate.

This application further discloses, as one embodiment, the following substrate processing method. The elevating mechanism includes a bag member for moving up and down the polishing pad by expansion and contraction caused by inflow and outflow of a fluid. The lowering step is configured to cause the fluid to flow in the bag member until the polishing pad contacts the reference surface. The measuring step is configured to measure an amount of bulge of the bag member until the polishing pad contacts the reference surface based on an image taken by an imaging member for imaging the bag member to measure the amount of abrasion of the polishing pad based on the measured amount of bulge of the bag member.

This application further discloses, as one embodiment, the following substrate processing method. The elevating mechanism includes a bag member for moving up and down the polishing pad by expansion and contraction caused by inflow and outflow of a fluid. The lowering step is configured to cause the fluid to flow in the bag member until the polishing pad contacts the reference surface. The measuring step is configured to measure the amount of abrasion of the polishing pad based on an amount of inflow of the fluid to the bag member until the polishing pad contacts the reference surface.

This application further discloses, as one embodiment, the following substrate processing method. The measuring step is further configured to measure the amount of abrasion of the polishing pad based on a value correlated with a behavior of the elevating mechanism when the polishing pad rises from a state of the polishing pad contacting the reference surface. The elevating mechanism includes a bag member for moving up and down the polishing pad by expansion and contraction caused by inflow and outflow of a fluid. The measuring step is configured to measure the amount of abrasion of the polishing pad based on an amount of outflow of the fluid from the bag member when the bag member is contracted from the state of the polishing pad contacting the reference surface.

### REFERENCE SIGNS LIST

100 . . . table
100a . . . support surface
222, 242 . . . polishing pad
222c . . . polishing surface
223 . . . bag member (air bag)
226, 246 . . . pad holder
227, 247 . . . holder elevating mechanism
260 . . . elevating mechanism
262 . . . flowmeter
264 . . . imaging member (camera)
270 . . . abrasion amount measurement member
300 . . . supporting member
301a, 301b . . . support surface
620 . . . swing arm
1000 . . . substrate processing apparatus
WF . . . substrate
WF-a . . . surface to be polished

What is claimed is:

1. A substrate processing apparatus comprising:
a table for supporting a substrate with a surface to be polished facing upward;
a pad holder for holding a polishing pad for polishing the substrate supported by the table;
an elevating mechanism for moving up and down the polishing pad held to the pad holder; and
an abrasion amount measurement member configured to lower the polishing pad by the elevating mechanism and measure an amount of abrasion of the polishing pad based on a value correlated with a behavior of the elevating mechanism until the polishing pad contacts a reference surface.

2. The substrate processing apparatus according to claim 1, further comprising:
a swing mechanism for swinging the pad holder in a radial direction of the substrate; and
a supporting member having a support surface for supporting the polishing pad swung to an outside of the table by the swing mechanism, wherein
the elevating mechanism includes a holder elevating mechanism for moving up and down the pad holder,
the reference surface is the support surface of the supporting member, and
the abrasion amount measurement member is configured to measure the amount of abrasion of the polishing pad based on information on a height of the pad holder when the pad holder is lowered by the holder elevating mechanism until the polishing pad contacts the support surface of the supporting member.

3. The substrate processing apparatus according to claim 1, wherein
the elevating mechanism includes a holder elevating mechanism for moving up and down the pad holder,
the reference surface is the surface to be polished of the substrate, and
the abrasion amount measurement member is configured to measure the amount of abrasion of the polishing pad based on information on a height of the pad holder when the pad holder is lowered by the holder elevating mechanism until the polishing pad contacts the surface to be polished of the substrate.

4. The substrate processing apparatus according to claim 2, wherein
the abrasion amount measurement member is configured to compare information on a height of the pad holder with respect to a polishing pad as a reference with information on a height of the pad holder with respect to a polishing pad as a measurement object to measure the amount of abrasion of the polishing pad as the measurement object.

5. The substrate processing apparatus according to claim 1, wherein
the elevating mechanism includes a bag member mounted to the pad holder, and the bag member is for moving up and down the polishing pad by expansion and contraction caused by inflow and outflow of a fluid, and
the abrasion amount measurement member includes an imaging member for imaging the bag member, and the abrasion amount measurement member is configured to measure an amount of bulge of the bag member until the polishing pad contacts the reference surface based on an image taken by the imaging member to measure the amount of abrasion of the polishing pad based on the measured amount of bulge of the bag member.

6. The substrate processing apparatus according to claim 5, wherein
the abrasion amount measurement member is configured to compare an amount of bulge of the bag member with respect to a polishing pad as a reference with an amount of bulge of the bag member with respect to a polishing pad as a measurement object to measure the amount of abrasion of the polishing pad as the measurement object.

7. The substrate processing apparatus according to claim 1, wherein
the elevating mechanism includes a bag member mounted to the pad holder, and the bag member is for moving up and down the polishing pad by expansion and contraction caused by inflow and outflow of a fluid, and
the abrasion amount measurement member includes a flowmeter configured to measure an amount of inflow of the fluid to the bag member, and the abrasion amount measurement member is configured to measure the amount of abrasion of the polishing pad based on the amount of inflow of the fluid to the bag member until the polishing pad contacts the reference surface.

8. The substrate processing apparatus according to claim 7, wherein
the abrasion amount measurement member is configured to compare an amount of inflow of a fluid to the bag member with respect to a polishing pad as a reference with an amount of inflow of a fluid to the bag member with respect to a polishing pad as a measurement object to measure the amount of abrasion of the polishing pad as the measurement object.

9. The substrate processing apparatus according to claim 1, wherein
the abrasion amount measurement member is further configured to measure the amount of abrasion of the polishing pad based on a value correlated with a behavior of the elevating mechanism when the polishing pad rises from a state of the polishing pad contacting the reference surface by the elevating mechanism,
the elevating mechanism includes a bag member mounted to the pad holder, and the bag member is for moving up and down the polishing pad by expansion and contraction caused by inflow and outflow of a fluid, and
the abrasion amount measurement member includes a flowmeter configured to measure an amount of outflow of the fluid from the bag member, and the abrasion amount measurement member is configured to measure the amount of abrasion of the polishing pad based on an amount of outflow of the fluid when the bag member is contracted from the state of the polishing pad contacting the reference surface.

10. The substrate processing apparatus according to claim 9, wherein
the abrasion amount measurement member is configured to compare an amount of outflow of a fluid from the bag member with respect to a polishing pad as a reference with an amount of outflow of a fluid from the bag member with respect to a polishing pad as a measurement object to measure the amount of abrasion of the polishing pad as the measurement object.

11. A substrate processing method comprising:
a lowering step of lowering a polishing pad for polishing a substrate supported to a table with a surface to be polished facing upward by an elevating mechanism until the polishing pad contacts a reference surface; and
a measuring step of measuring an amount of abrasion of the polishing pad based on a value correlated with a behavior of the elevating mechanism until the polishing pad contacts the reference surface by the lowering step.

12. The substrate processing method according to claim 11, wherein
the elevating mechanism includes a holder elevating mechanism for moving up and down a pad holder for holding the polishing pad,
the reference surface is a support surface of a supporting member for supporting the polishing pad swung to an outside of the table,
the lowering step is configured to lower the pad holder by the holder elevating mechanism until the polishing pad contacts the support surface, and
the measuring step is configured to measure the amount of abrasion of the polishing pad based on information on a height of the pad holder when the pad holder is lowered by the holder elevating mechanism until the polishing pad contacts the support surface.

13. The substrate processing method according to claim 11, wherein
the elevating mechanism includes a holder elevating mechanism for moving up and down a pad holder for holding the polishing pad,
the reference surface is the surface to be polished of the substrate,
the lowering step is configured to lower the pad holder by the holder elevating mechanism until the polishing pad contacts the surface to be polished of the substrate, and
the measuring step is configured to measure the amount of abrasion of the polishing pad based on information on a height of the pad holder when the pad holder is lowered by the holder elevating mechanism until the polishing pad contacts the surface to be polished of the substrate.

14. The substrate processing method according to claim 11, wherein
the elevating mechanism includes a bag member for moving up and down the polishing pad by expansion and contraction caused by inflow and outflow of a fluid,
the lowering step is configured to cause the fluid to flow in the bag member until the polishing pad contacts the reference surface, and
the measuring step is configured to measure an amount of bulge of the bag member until the polishing pad contacts the reference surface based on an image taken by an imaging member for imaging the bag member to measure the amount of abrasion of the polishing pad based on the measured amount of bulge of the bag member.

15. The substrate processing method according to claim 11, wherein
the elevating mechanism includes a bag member for moving up and down the polishing pad by expansion and contraction caused by inflow and outflow of a fluid,
the lowering step is configured to cause the fluid to flow in the bag member until the polishing pad contacts the reference surface, and
the measuring step is configured to measure the amount of abrasion of the polishing pad based on an amount of inflow of the fluid to the bag member until the polishing pad contacts the reference surface.

16. The substrate processing method according to claim 11, wherein
the measuring step is further configured to measure the amount of abrasion of the polishing pad based on a value correlated with a behavior of the elevating mechanism when the polishing pad rises from a state of the polishing pad contacting the reference surface,
the elevating mechanism includes a bag member for moving up and down the polishing pad by expansion and contraction caused by inflow and outflow of a fluid, and
the measuring step is configured to measure the amount of abrasion of the polishing pad based on an amount of outflow of the fluid from the bag member when the bag member is contracted from the state of the polishing pad contacting the reference surface.
